(19) United States
(12) Patent Application Publication
(10) Pub. No.: US 2025/0151207 A1
(43) Pub. Date: May 8, 2025

(54) WIRING SUBSTRATE AND ITS MANUFACTURING METHOD

(71) Applicant: Shanghai AVIC Optoelectonics Co., Ltd., Shanghai (CN)

(72) Inventor: Akira FUJITA, Kawasaki (JP)

(73) Assignee: Shanghai AVIC Optoelectronics Co., Ltd., Shanghai (CN)

(21) Appl. No.: 18/934,300

(22) Filed: Nov. 1, 2024

(30) Foreign Application Priority Data
Nov. 8, 2023 (JP) 2023-190725

(51) Int. Cl. H05K 3/38; H01L 23/485; H01L 23/498; H05K 1/02; H05K 1/11; H05K 1/18

(52) U.S. Cl. CPC H05K 3/388; H01L 23/485; H01L 23/49838; H05K 1/0271; H05K 1/111; H05K 1/181; H05K 2201/09472

(57) ABSTRACT

A wiring substrate having, on a surface, a mounting pad for mounting a semiconductor device comprises a metal pad, an insulating layer, and a metal layer. A pad area of the mounting pad is defined by an opening section formed in the insulating layer. The wiring substrate further comprises an etching barrier layer provided between an upper surface of the metal pad and the insulating layer. The etching barrier layer is provided to surround a lower end of the opening section and extends outward from the lower end of the opening section to the outer periphery.

### CROSS-REFERENCE TO RELATED APPLICATIONS

The present application claims the benefit of Japanese Patent Application No. 2023-190725, filed on Nov. 8, 2023. The entire disclosure of Japanese Patent Application No. 2023-190725 is incorporated by reference herein.

### FIELD OF THE INVENTION

The present application relates to a wiring substrate for mounting a semiconductor and its manufacturing method.

### BACKGROUND OF THE INVENTION

A semiconductor package substrate, a printed board or the like is used as a wiring substrate for mounting a semiconductor.

In such a substrate, a wiring circuit pattern is formed, and then the wiring circuit is insulated and protected with a solder resist. At the same time, a mounting pad for mounting a semiconductor is formed.

Further, a solder mask defined (SMD) structure is known as the mounting pad, as is disclosed in Unexamined Japanese Patent Application Publication No. 2010-140990.

In a mounting pad of an SMD structure, a solder resist layer (an insulating layer) is formed on an electrode pad, and then an opening section is provided in the solder resist layer to expose a part of the pad, as is disclosed in Unexamined Japanese Patent Application Publication No. 2010-140990. The surface of the pad exposed through the opening section is treated by etching, and a Ni plated film and an Au plated film is formed on the electrode pad.

In the pad of an SMD structure in Unexamined Japanese Patent Application Publication No. 2010-140990, an undercut part is formed beneath the opening of the solder resist layer when a surface etching of the electrode pad is performed. An etchant may penetrate between the electrode pad and the solder resist layer through this undercut part, causing peeling of the solder resist layer from the electrode pad. The peeling of the solder resist layer may be caused not only by penetration of an etchant but also by other cause such as thermal loads during a formation process of a Ni plated film or penetration of a Ni plating solution.

In addition, even if peeling does not occur during the manufacturing process, the solder resist layer may be peeled from the electrode pad due to an external stress originated by a factor such as heat or water, during long-term use of the product.

Therefore, a wiring substrate that can prevent peeling of the insulating layer around the pad, and its manufacturing are awaited.

### SUMMARY OF THE INVENTION

A wiring substrate according to a first aspect of the present disclosure is a wiring substrate having, on a surface, a mounting pad for mounting a semiconductor device, the wiring substrate comprising:
a metal pad provided on one of main surfaces of a base material;
an insulating layer being provided to cover a side surface of the metal pad and at least part of an upper surface of the metal pad, and being provided with an opening section that exposes a part of the upper surface of the metal pad; and
a metal layer provided on the metal pad exposed through the opening section, wherein
a pad area of the mounting pad is defined by the opening section formed in the insulating layer, and
the wiring substrate further comprises an etching barrier layer provided between the upper surface of the metal pad and the insulating layer, the etching barrier layer being provided to surround a lower end of the opening section and extending outward from the lower end of the opening section toward an outer periphery.

A manufacturing method of a wiring substrate according to a second aspect of the present disclosure is a manufacturing method of a wiring substrate having, on a surface, a mounting pad for mounting a semiconductor device, the manufacturing method includes steps of:
forming an etching barrier layer on a metal pad provided on one of main surfaces of a base material;
forming an insulating layer covering a side surface of the metal pad and at least part of an upper surface of the metal pad, and being provided with an opening section that exposes a part of the upper surface of the metal pad; and
forming a metal layer on the metal pad exposed through the opening section, wherein
a pad area of the mounting pad is defined by the opening section formed in the insulating layer, and
the etching barrier layer is formed to surround a lower end of the opening section and extend outward from the lower end of the opening section toward an outer periphery.

It is to be understood that both the foregoing general description and the following detailed description are exemplary and explanatory and are not restrictive of this disclosure.

### BRIEF DESCRIPTION OF DRAWINGS

A more complete understanding of this application can be obtained when the following detailed description is considered in conjunction with the following drawings, in which:

FIG. 1 is a partial top view of a wiring substrate according to Embodiment 1;

FIG. 2 is a sectional view taken along the line II-II shown in FIG. 1;

FIG. 3 is a partial enlarged sectional view of a mounting pad;

FIG. 4 is a diagram illustrating a modified embodiment;

FIGS. 5A to 5D are each a diagram for describing a manufacturing method of a wiring substrate according to Embodiment 1;

FIGS. 6A to 6C are each a diagram for describing the manufacturing method of a wiring substrate according to Embodiment 1;

FIG. 7 is a partial top view of a wiring substrate according to Embodiment 2;

FIG. 8 is a sectional view taken along the line VIII-VIII shown in FIG. 7;

FIGS. 9A to 9C are each a diagram for describing a manufacturing method of a wiring substrate according to Embodiment 2;

FIG. 10 is a partial top view illustrating a modified embodiment; and

FIG. 11 is a sectional view taken along the line XI-XI shown in FIG. 10.

### DETAILED DESCRIPTION OF THE INVENTION

Hereinafter, a wiring substrate and its manufacturing method according to embodiments will be described, with reference to drawings.

### Embodiment 1

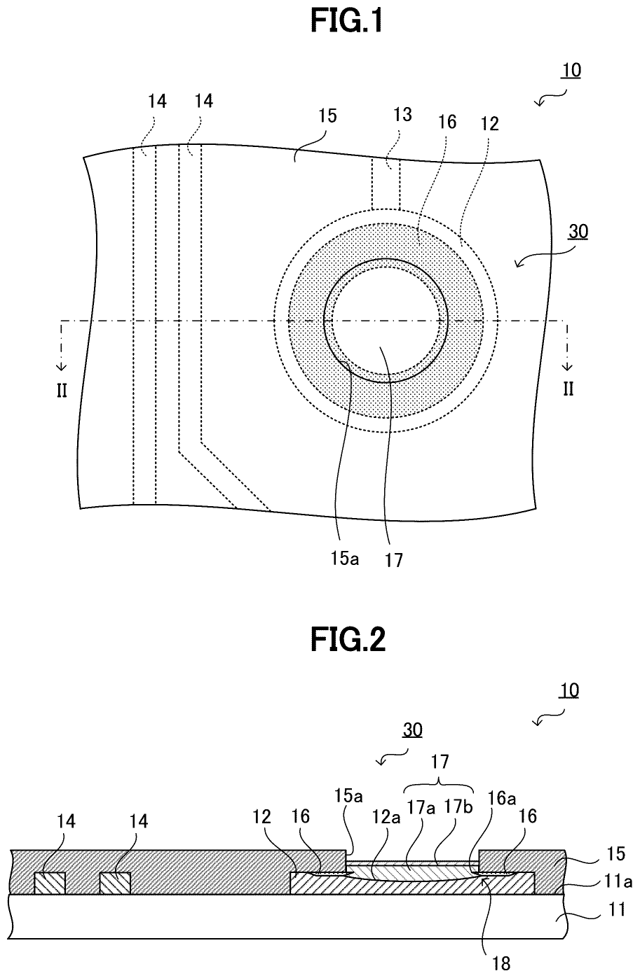

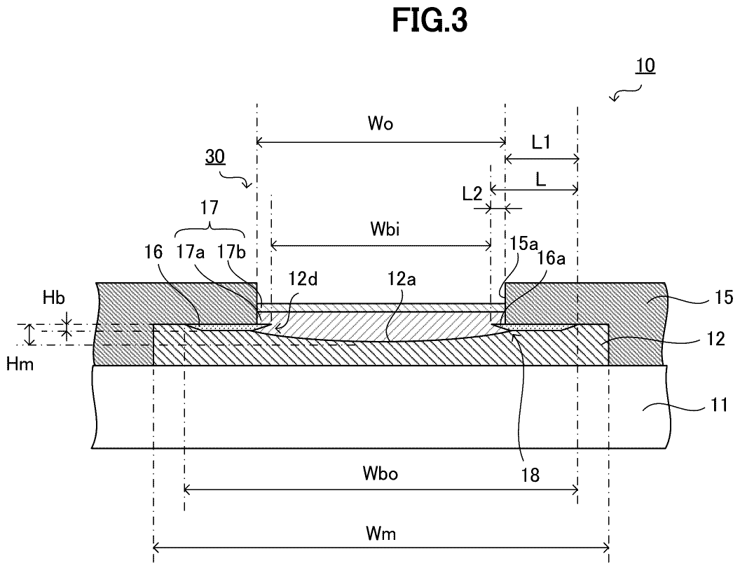

A wiring substrate 10 according to the present embodiment is shown in FIGS. 1 to 3. In the present embodiment, description are made using a semiconductor package substrate, on which a semiconductor device is mounted, as an example of the wiring substrate 10. FIG. 1 is a partial top view of the wiring substrate 10. FIG. 2 is a sectional view taken along the line II-II shown in FIG. 1. Furthermore, FIG. 3 is a partial enlarged sectional view of a mounting pad 30.

As illustrated in FIGS. 1 to 3, the wiring substrate 10 comprises a base material 11, a metal pad 12, a terminal wiring layer 13, wiring layers 14, an insulating layer 15, an etching barrier layer 16, and a metal layer 17. The wiring substrate 10 comprises a plurality of mounting pads 30 on its surface. The mounting pads 30 are composed of the metal pad 12 and the metal layer 17. The mounting pad 30 is a solder mask defined (SMD) terminal. A pad area of the mounting pad 30 is defined by an opening section 15a formed in the insulating layer 15.

The base material 11 is made of a material, such as polyimide, liquid crystal polymer, polyethylene terephthalate (PET), epoxy resin, phenolic resin, glass epoxy resin, glass, or silicon wafer. The metal pad 12, the terminal wiring layer 13, and the wiring layers 14 are formed on one main surface 11a of the base material 11. Furthermore, the insulating layer 15 for insulating and protecting the terminal wiring layers 13 and the wiring layers 14 is provided on the main surface 11a of the base material 11. The insulating layer 15 is provided to cover the outer peripherals of the metal pad 12 as well.

The metal pad 12 is made of a metal, such as copper. As illustrated in FIG. 1, the metal pad 12 is formed into a circular shape in a plan view of the metal pad 12. Furthermore, a side surface and at least part of an upper surface of the metal pad 12 are covered with the insulating layer 15. A part of the upper surface of the metal pad 12 is exposed through the opening section 15a formed in the insulating layer 15. Furthermore, the metal pad 12 is connected to the terminal wiring layer 13, as illustrated in FIG. 1.

The upper surface of the metal pad 12 is etched, as is described in detail below, so as to have a recess section 12a, as illustrated in FIGS. 2 and 3. A depth Hm of the recess section 12a is any value equal to approximately 10% to 50% of the thickness of the metal pad 12. For example, the depth Hm of the recess section 12a is 1 to 5 μm, as an example, 3 μm. The depth Hm of the recess section 12a is a depth of the most recessed part relative to the upper surface of the metal pad 12, as illustrated in FIG. 3.

The terminal wiring layer 13 and the wiring layers 14 are made of a metal, such as copper. The terminal wiring layer 13 and the wiring layers 14 are covered with the insulating layer 15, thereby being insulated and protected.

The metal layer 17 is provided to cover the upper surface of the metal pad 12 exposed through the opening section 15a of the insulating layer 15. The metal layer 17 is formed by the electroless nickel immersion gold (ENIG) treatment or the electroless nickel electroless palladium immersion gold (ENEPIG) treatment. In the present embodiment, an example is described in which the ENIG treatment is used. The metal layer 17 comprises a Ni film 17a and an Au film 17b. The Ni film 17a of the metal layer 17 fills the recess section 12a of the metal pad 12 and is also provided within the opening section 15a. The metal layer 17 (Ni film 17a) is provided to cover a protrusion section 16a of the etching barrier layer 16. In other words, the metal layer 17 (Ni film 17a) is formed to extend to the inside of an undercut formed beneath the inner side end of the etching barrier layer 16. Specifically, the metal layer 17 (Ni film 17a) is formed to cover a part beneath the protrusion section 16a of the etching barrier layer 16, as illustrated in FIG. 3. A step 18 due to a difference in film thickness is formed between the etching barrier layer 16 and the Ni film 17a.

The insulating layer 15 is made of an insulating material, such as polyimide. The opening section 15a for partially exposing the upper surface of the metal pads 12 is formed in the insulating layer 15. The shape of a terminal is defined by the opening section 15a. The opening section 15a is formed to have a circular shape in a plan view, as illustrated in FIG. 1. Although an example in which the insulating layer 15 is made of varnish-type photosensitive polyimide is described in the present embodiment, the photosensitive polyimide may alternatively be film-type. Furthermore, a material of the insulating layer 15 is not limited to a polyimide resin material. The insulating layer 15 may be made of another material provided that it has insulation properties. For example, the insulating layer 15 may be made of a material, such as phenol resin material, epoxy resin material, urethane material, or polyester material. Alternatively, the insulating layer 15 may be made of a thermosetting material other than photosensitive thermosetting materials.

The etching barrier layer 16 is provided between the upper surface of the metal pad 12 and the insulating layer 15 mounted on the metal pad 12. Furthermore, the etching barrier layer 16 is provided to surround a lower end of the opening section 15a. Furthermore, the etching barrier layer 16 extends radially outward from the lower end of the opening section 15a of the insulating layer 15. The etching barrier layer 16 thus has an annular planar shape, as illustrated in FIG. 1. The etching barrier layer 16 is made of an inorganic material different from the material of which the metal pad 12 is made. A material is used as the inorganic material that can improve the adhesion between the metal pad 12 and the insulating layer 15 and is not susceptible to etching by an etchant used in surface etching treatment of the metal pad 12 prior to the formation of the metal layer 17. In view of these, the etching barrier layer 16 is made of a material, such as Ni, Ti, or Cr, in the case where the metal pad 12 is made of Cu.

As illustrated in FIGS. 2 and 3, the etching barrier layer 16 is provided to partially cover the upper surface of the metal pad 12. Alternatively, the etching barrier layer 16 may be provided to cover the entire upper surface of the metal pad 12. A width L1 of a part of the etching barrier layer 16 extending between the insulating layer 15 and the metal pad 12 is preferably larger than an undercut amount expected for the etching to form the recess section 12a of the metal pad 12. The undercut amount varies depending on the depth Hm and/or the properties of the etchant. When a typical etchant is used, an undercut whose undercut amount is equal to 0.1 to 1 times of the etching depth (corresponding to the depth Hm) may be formed. When an etchant that is likely to form an undercut is used, an undercut whose undercut amount is equal to 1 to 3 times of the etching depth (corresponding to the depth Hm) may be formed. Thus, the width L1 is preferably larger than a value in the range of 0.1 to 3 times of the depth Hm. In the case where the undercut amount is smaller than the minimum resolution dimension in the formation of an etching barrier layer, the width L1 is preferably larger than the minimum resolution dimension.

Furthermore, as illustrated in FIGS. 1 and 2, since the inner end of the etching barrier layer 16 protrudes toward the center of the opening section 15a relative to the inner peripheral surface of the opening section 15a, the etching barrier layer 16 has the protrusion section 16a. Furthermore, at least an end of the etching barrier layer 16 on the opening section 15a side is in contact with the metal layer 17 (Ni film 17a). A thickness Hb of the etching barrier layer 16 is preferably 1 μm or larger. Furthermore, when the etching barrier layer 16 is made of Ni, a high conduction loss may be caused since Ni is a ferromagnetic material. Thus, depending on the application of the wiring substrate 10, it may be preferable to provide the etching barrier layer 16 only around the lower end of the opening section 15a without extending it to the outer edge of the metal pad 12.

The metal layer 17 is provided to cover the upper surface of the metal pad 12 exposed through the opening section 15a of the insulating layer 15. The metal layer 17 is formed by the electroless nickel immersion gold (ENIG) treatment. The metal layer 17 comprises the Ni film 17a and the Au film 17b. The Ni film 17a of the metal layer 17 fills the recess section 12a of the metal pad 12 and is provided within the opening section 15a. The metal layer 17 (Ni film 17a) is formed to extend into an undercut 12d formed beneath the inner end of the etching barrier layer 16. Specifically, the metal layer 17 (Ni film 17a) is formed to cover the protrusion section 16a of the etching barrier layer 16, as illustrated in FIG. 3, by a process separate from a process for forming the etching barrier layer 16. The step 18 due to a difference in film thickness is formed between the etching barrier layer 16 and the Ni film 17a.

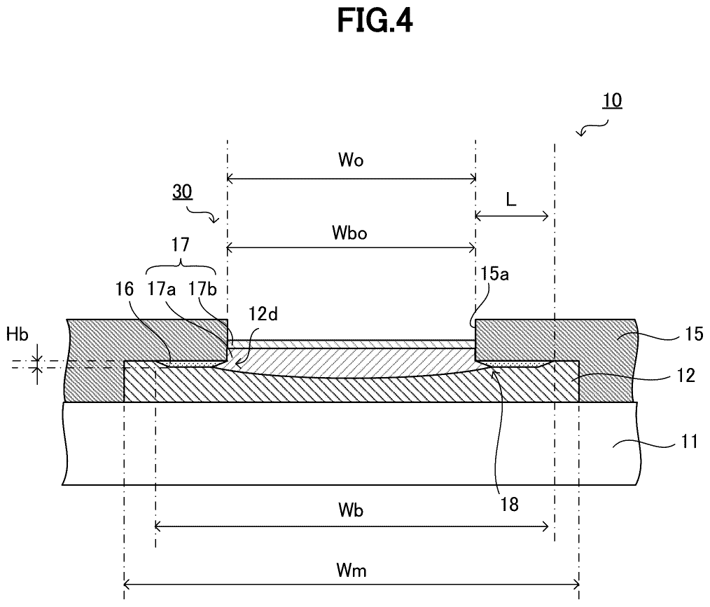

Alternatively, as illustrated in FIG. 4, the inner end of the etching barrier layer 16 may not protrude relative to the inner peripheral surface of the opening section 15a. FIG. 4 is a sectional view of the mounting pad 30 taken along the line corresponding to the line II-II shown in FIG. 1. The protrusion section 16a of the etching barrier layer 16 may be broken and cause a foreign matter defect. In such a case, it is preferable to form the etching barrier layer 16 so as not to protrude relative to the inner peripheral surface of the opening section 15a. In the case where the etching barrier layer 16 is not provided with the protrusion section 16a, it is preferable that the etching barrier layer 16 covers the lower end of the opening section 15a, as illustrated in FIG. 4, in order to prevent penetration of an etchant and penetration of a plating solution. Thus, the inner end of the etching barrier layer 16 is located at the lower end of the opening section 15a. In other words, it is preferable that an inner diameter of the etching barrier layer 16 is equal to an inner diameter of the opening section 15a. Furthermore, the Ni film 17a of the metal layer 17 covers the etching barrier layer 16 at the undercut 12d formed beneath the inner end of the etching barrier layer 16, as illustrated in FIG. 4. The step 18 due to a difference in film thickness is formed between the etching barrier layer 16 and the Ni film 17a.

Next, as illustrated in FIG. 3, the diameter of the metal pad 12 is denoted as Wm, and the inner diameter of the opening section 15a of the insulating layer 15 is denoted as the width Wo. Furthermore, Wbi indicates the inner diameter of the etching barrier layer 16, and Wbo indicates the outer diameter of the etching barrier layer 16. L1 indicates the length of a part of the etching barrier layer 16 located between the metal pad 12 and the insulating layer 15. L2 indicates the length by which the protrusion section 16a protrudes from the inner peripheral surface of the opening section 15a. The width L of the etching barrier layer 16 is equal to the sum of the length L1 and the length L2 (L=L1+L2). Furthermore, the etching barrier layer 16 may not protrude into the opening section 15a, as illustrated in FIG. 4, but preferably covers the lower end of the opening section 15a. The L2 of the etching barrier layer 16 therefore satisfies the inequality L2≥0.

Furthermore, the inner diameter Wo of the opening section 15a is equal to or larger than the inner diameter Wbi of the etching barrier layer 16 (Wbi≤Wo). In addition, the inner diameter Wo of the opening section 15a is smaller than the outer diameter Wm of the metal pad 12 (Wo<Wm). Therefore, the inner diameter Wbi of the etching barrier layer 16, the inner diameter Wo of the opening section 15a, and the outer diameter Wm of the metal pad 12 satisfy the relationship expressed by Wbi≤Wo<Wm.

Next, the etching barrier layer 16 may be formed to partially cover the upper surface of the metal pad 12. The etching barrier layer 16 may be formed to reach the end of the outer periphery of the metal pad 12. Therefore, the outer diameter Wbo of the etching barrier layer 16 is equal to or smaller than the outer diameter Wm of the metal pad 12 (Wbo≤Wm).

In the wiring substrate 10 of the present embodiment, the etching barrier layer 16 improves the adhesion between the metal pad 12 and the insulating layer 15. Thus, peeling of the insulating layer 15 from the metal pad 12 can be suppressed during an etching process or a plating process, even when the undercut 12d is formed beneath the insulating layer 15 during a pretreatment etching prior to the formation of the Ni film 17a of the metal layer 17.

For example, one method for suppressing peeling of an insulating layer is to reduce an undercut in the insulating layer. This may be realized by reducing an etching amount in the pretreatment etching of the upper surface of a pad. In recent years, however, thinning or densification of wiring has been awaited, and the dimension of an opening section for exposing the pad has been narrowed. As a result, a problem has arisen that development residues produced during formation of the opening section in the insulating layer is likely to remain on the pad surface, thereby contaminating the pad surface. The contaminated pad surface may cause a defect when a Ni plated film is formed. The pad surface thus must undergo a sufficient pretreatment etching. In the wiring substrate 10 of the present embodiment, the metal pad 12 and the insulating layer 15 has a good adhesion therebetween. The wiring substrate 10 can thus endure stresses in the manufacturing process, such as stresses in formation of a Ni plated film or formation of an Au plated film, while allowing for formation of the undercut 12d.

Furthermore, in the case where peeling does not occur during the manufacturing process, the etching barrier layer 16 improves the adhesion between the metal pad 12 and the insulating layer 15, and thus can suppress peeling of the insulating layer 15 due to external stresses, such as heat or water, during long-term use of the product. Furthermore, the etching barrier layer 16 can suppress dispersion of metals contained in the metal pad 12, especially, Cu into the insulating layer 15, and thus enhance adhesion reliability.

Next, a method for manufacturing the wiring substrate 10 according to the present embodiment will be described, with reference to the drawings.

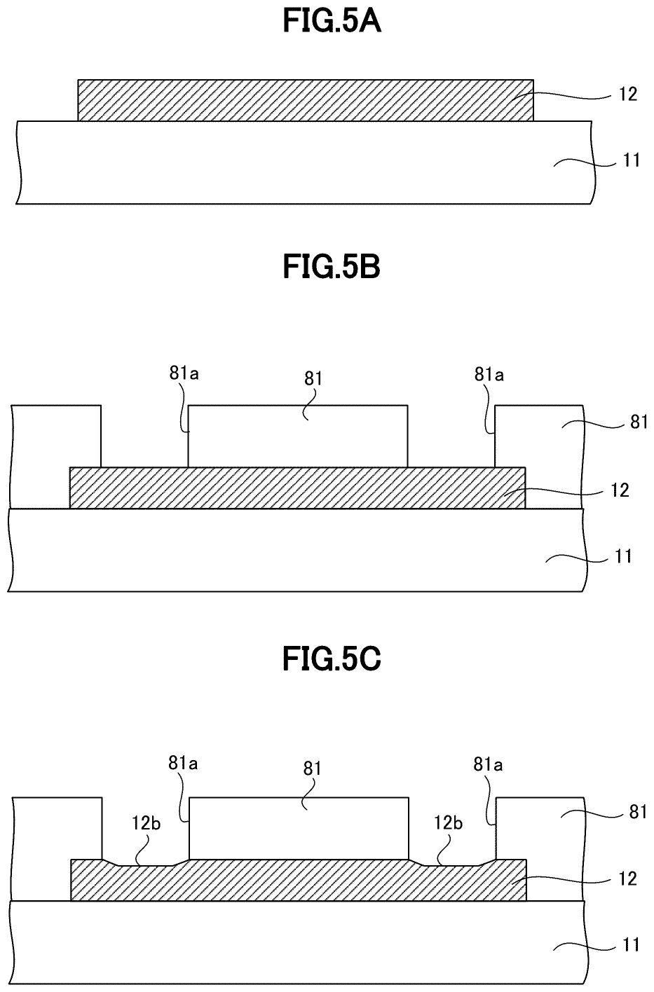

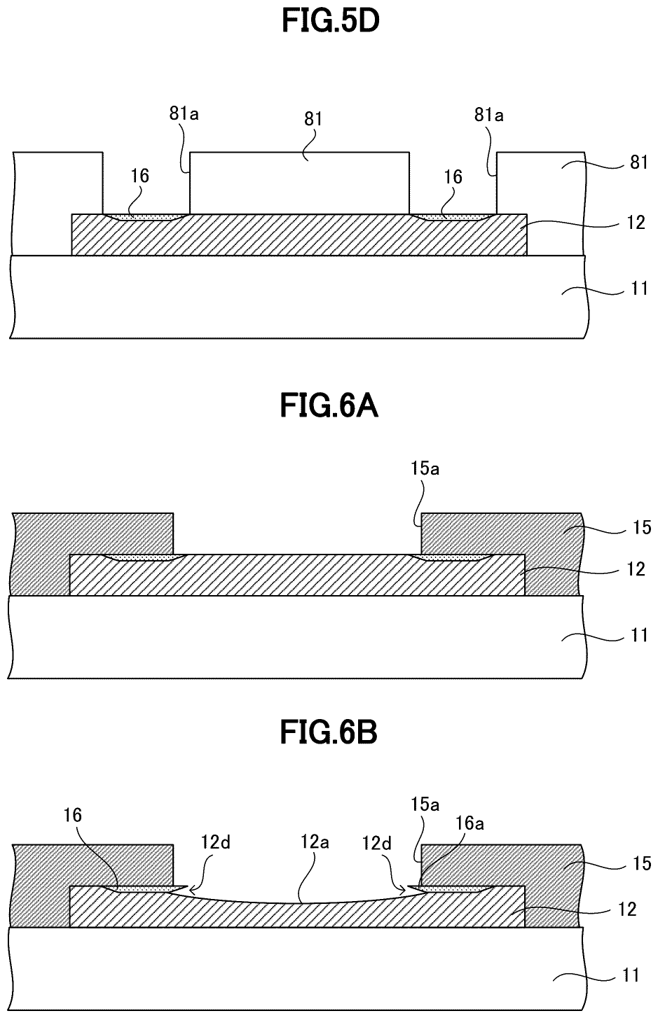

First, a metal pad 12 is formed on a base material 11, as illustrated in FIG. 5A. The metal pad 12 is formed by the following method, for example. First, a seed layer (not illustrated) is formed. The seed layer may be provided on the base material 11 beforehand. Then, a resist (not illustrated) is formed by applying a dry film and performing exposure development, the resist having an opening section formed at an area to be provided with the metal pad 12. Electrolytic Cu plating on the seed layer is performed, thus forming a copper layer. Subsequently, the resist is moved, and then the seed layer other than a wiring layer is removed, thereby forming the metal pad 12.

Next, a resist 81 is formed by coating the base material 11 and the metal pad 12 with a resist solution and performing exposure development, the resist 81 having an opening 81a formed at an area to be provided with an etching barrier layer 16, as illustrated in FIG. 5B. Furthermore, in the case where the etching barrier layer 16 does not protrude into the opening section 15a of the insulating layer 15 (in the case of L2=0), the position of the opening 81a of the resist 81 is adjusted at the time of designing of the resist.

Next, the surface of the metal pad 12 exposed through the opening 81a is etched with an etchant, thus forming the recess section 12b, as illustrated in FIG. 5C.

Next, an etching barrier layer 16 is formed on the recess section 12b by dry plating (such as spattering), wet plating, lamination method using a metal foil, or the like, as illustrated in FIG. 5D. An inorganic material is used as a material for the etching barrier layer 16. An inorganic material is used as said inorganic material that can improve the adhesion between the metal pad 12 and the insulating layer 15, and is not susceptible to etching by an etchant used in the surface etching treatment of the metal pad 12 prior to formation of the metal layer 17. In the case where the metal pad 12 is made of Cu, Ni, Ti, or Cr, or the like, may be used as the inorganic material. A selective etchant that can remove only Cu is used as an etchant. Any commercially available selective etchant may be used, depending on the inorganic material used.

Etchants suitable for use includes, but not limited to, following etchants. In the case where Ni is used as the inorganic material, a neutral to weak alkaline etchant (for example, SF-5420, MEC COMPANY LTD.) can be used. In the case where Ti is used as the inorganic material, a (sulfuric acid-) hydrogen peroxide-phosphoric acid etchant (for example, WLC-C2, Mitsubishi Gas Chemical Trading, Inc.) can be used. In the case where Cr is used as the inorganic material, a sulfuric acid-hydrogen peroxide etchant (for example, CB-801Y, MEC COMPANY LTD.) may be used.

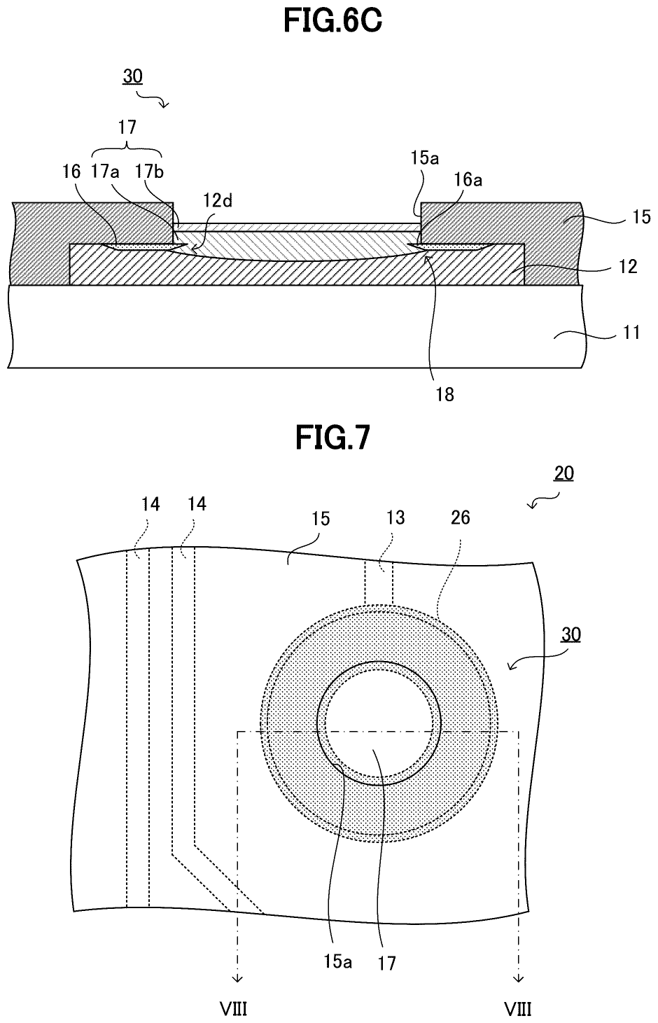

Next, the resist 81 is peeled. Subsequently, an insulating layer 15 is formed by spraying varnish-type photosensitive polyimide, and then by baking and hardening, the insulating layer 15 having an opening section 15a corresponding to the pad area of a mounting pad 30, as illustrated in FIG. 6A. The insulating layer 15 may be made of film-type photosensitive polyimide. The material for the insulating layer 15 is not limited to polyimide resin materials, and may be other material that has insulation properties. For example, the insulating layer 15 may be made of phenol resin material, epoxy resin material, urethane material, polyester material or the like. Furthermore, a thermoset material other than photosensitive thermoset materials may be used as the material for the insulating layer 15.

The surface of the metal pad 12 exposed through the opening section 15a is etched with an etchant. For example, in a case where the metal pad 12 is made of copper and the etching barrier layer 16 is made of Ni, a neutral to weak alkaline etchant (for example, SF-5420, MEC COMPANY LTD.) is used as the etchant. With this etching, a recess section 12a is formed on the surface of the metal pad 12, as illustrated in FIG. 6B. Furthermore, since wet etching is isotropic etching, a part beneath the inner end of the etching barrier layer 16 is also etched, thereby forming an undercut 12d, as illustrated in FIG. 6B.

Next, a Ni film (Ni plated film) 17a and an Au film (Au plated film) 17b are formed by the ENIG treatment on the recess section 12a, as illustrated in FIG. 6C. With this, the Ni plated film 17a is formed inside the undercut 12d as well. The Ni plated film 17a is formed to cover a protrusion section 16a of the etching barrier layer 16. Furthermore, a step 18 due to a difference in film thickness is formed between the etching barrier layer 16 and the Ni plated film 17a. Alternatively, the metal layer 17 may be formed by the ENEPIG treatment.

With the above-described method, the wiring substrate 10 is manufactured.

The manufacturing method of the wiring substrate 10 according to the present embodiment involves a step of forming the etching barrier layer 16 after formation of the metal pad 12, and can thus suppress peeling of the insulating layer 15 from the upper surface of the metal pad 12 during the surface etching treatment of the metal pad 12. Furthermore, by providing the etching barrier layer 16, the adhesion between the insulating layer 15 and the metal pad 12 can be improved, and thus peeling of the insulating layer 15 due to stresses applied in the formation process of the metal layer 17 can be suppressed.

Furthermore, since the etching barrier layer 16 can improve the adhesion between the metal pad 12 and the insulating layer 15, peeling of the insulating layer 15 due to external stresses can be suppressed, during long-term use of the product comprising the wiring substrate 10. Furthermore, since the etching barrier layer 16 can suppress dispersion of metals contained in the metal pad 12, especially, Cu into the insulating layer 15, adhesion reliability can be enhanced.

### Embodiment 2

A wiring substrate 20 according to Embodiment 2 will be described, with reference to the drawings. The wiring substrate 20 of the present embodiment differs from the wiring substrate 10 according to Embodiment 1 in the shape of an etching barrier layers 26. The component elements common to Embodiment 1 are denoted by the reference characters that are the same as in Embodiment 1, and detailed descriptions of them are omitted.

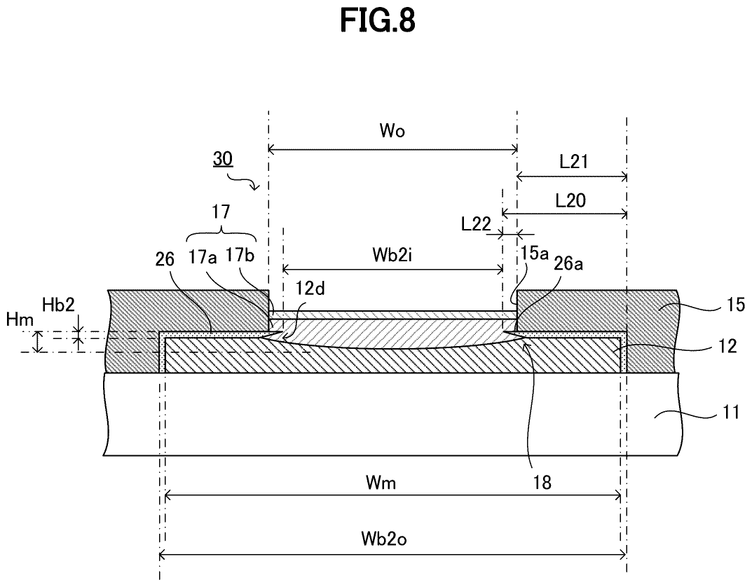

FIGS. 7 and 8 illustrate the wiring substrate 20 according to Embodiment 2. FIG. 7 is a partial top view of the wiring substrate 20, and FIG. 8 is a sectional view taken along the line VIII-VIII shown in FIG. 7.

As illustrated in FIGS. 7 and 8, the wiring substrate 20 comprises a base material 11, a metal pad 12, a terminal wiring layer 13, wiring layers 14, an insulating layer 15, an etching barrier layer 26, and a metal layer 17.

The etching barrier layers 26 is made of Ni, for example, as in Embodiment 1, and extends between the metal pad 12 and the insulating layer 15, as illustrated in FIG. 8. Furthermore, the etching barrier layer 26 is provided to surround the lower end of the opening section 15a. Furthermore, the etching barrier layer 26 extends radially outward from the lower end of the opening section 15a of the insulating layer 15 to the outer peripheral side edge of the metal pad 12. Furthermore, the etching barrier layer 26 is formed to cover the side surface of the outer periphery of the metal pad 12. The metal pad 12 is connected to the terminal wiring layer 13, as illustrated in FIG. 7. The etching barrier layer 26 thus covers the side surface of the metal pad 12 except for the part to which the terminal wiring layer 13 is connected.

Furthermore, the etching barrier layer 26 has an annular planar shape, as illustrated in FIG. 7. The etching barrier layer 26 is provided to cover the entire upper surface of the metal pad 12, except for the area in which the opening section 15a locates, as illustrated in FIGS. 7 and 8. Furthermore, the inner end of the etching barrier layer 26 protrudes inward relative to the inner peripheral surface of the opening section 15a, as illustrated in FIGS. 7 and 8. The etching barrier layer 26 thus has a protrusion section 26a. Furthermore, a thickness Hb2 of the etching barrier layer 26 is preferably 1 μm or larger. A width L21 of the part that extends between the insulating layer 15 and the metal pad 12 is preferably larger than the undercut amount expected for the etching to form the recess section 12a of the metal pad 12. The width L21 is preferably larger than a value in the range of 0.1 to 3 times of the depth Hm.

The metal layer 17 is provided to cover the upper surface of the metal pad 12 exposed through the opening section 15a of the insulating layer 15. In the present embodiment, the metal layer 17 is formed to exist in an undercut 12d formed beneath the inner end of the etching barrier layer 26. Specifically, the metal layer 17 is formed to cover the par beneath the protrusion section 26a of the etching barrier layer 26, as illustrated in FIG. 8. A step 18 due to a difference in film thickness is formed between the etching barrier layer 26 and the Ni film 17a.

As in Embodiment 1, the etching barrier layer 26 may not necessarily protrude inside the opening section 15a, but preferably covers the lower end of the opening section 15a. Thus, when the length by which the protrusion section 26a protrudes from the inner peripheral surface of the opening section 15a is denoted by L22, the length L22 satisfies the inequality L22≥0. Furthermore, the width L20 of the etching barrier layer 26 is equal to the sum of the length L21 and the length L22 (L20=L21+L22).

Next, the diameter of the metal pad 12 is denoted by Wm, and the inner diameter of the opening section 15a of the insulating layer 15 is denoted by Wo. Furthermore, the inner diameter of the etching barrier layer 26 is denoted by Wb2i, and the outer diameter of the etching barrier layer 26 is denoted by Wb2o. The inner diameter Wo of the opening section 15a is equal to or larger than the inner diameter Wb2i of the etching barrier layer 26 (Wb2≤sWo). In addition, the inner diameter Wo of the opening section 15a is smaller than the outer diameter Wm of the metal pad 12 (Wo<Wm). Thus, the inner diameter Wb2i of the etching barrier layer 26, the inner diameter Wo of the opening section 15a, and the outer diameter Wm of the metal pad 12 satisfy the relationship represented by Wb2i≤Wo<Wm.

Next, the etching barrier layer 26 extends from the lower end of the opening section 15a to the upper surface of the metal pad 12, and is formed to cover the side surface of the metal pad 12. Thus, in the present embodiment, the outer diameter Wb2o of the etching barrier layer 26 is larger than the outer diameter Wm of the metal pad 12 (Wb2o>Wm).

In the wiring substrate 20 according to the present embodiment the side surface of the metal pad 12 is covered by the etching barrier layer 26. With this, dispersion of metals, such as Cu, from the side surface of the metal pad 12 into the insulating layer 15 can be suppressed. As a result, deterioration and peeling of the insulating layer 15 can be suppressed, and peeling of the insulating layer 15 from the upper surface of the metal pad 12 is suppressed as in Embodiment 1.

Then, a manufacturing method of the wiring substrate 20 will be described, with reference to the drawings.

First, a metal pad 12 is formed on a base material 11, as in Embodiment 1.

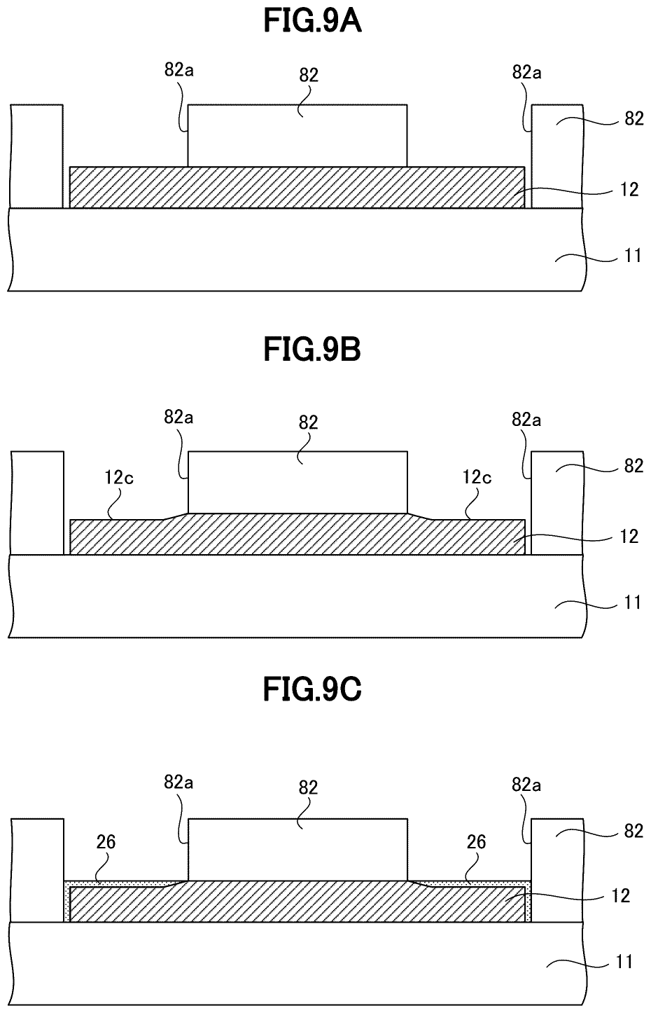

Then, a resist 82 is formed by coating the base material 11 and the metal pad 12 with a resist solution and performing exposure development, the resist 82 having an opening 82a formed at an area to be provided with an etching barrier layer 26. Specifically, in the present embodiment, the opening 82a is formed so that the side surface of the metal pad 12 is exposed through the resist 82, as illustrated in FIG. 9A, in order to form the etching barrier layer 26 over the side surface of the metal pad 12. Subsequently, the surface of the metal pad 12 exposed through the opening 82a is etched with an etchant, and thus forming a recess section 12c, as illustrated in FIG. 9B.

Then, an etching barrier layer 26 is formed on the recess section 12c, as illustrated in FIG. 9C, by dry plating (such as spattering), wet plating, or the like. The etching barrier layer 26 is formed by, for example, electroless Ni plating.

Then, the resist 82 is peeled. Following this step, an insulating layer 15 is formed on the base material 11, and surface etching of the metal pad 12 exposed through an opening section 15a of the insulating layer 15 is performed, as in Embodiment 1. Subsequently, ENIG treatment is performed, thus forming a metal layer 17 on the metal pad 12.

With the above-described method, the wiring substrate 20 is manufactured.

The manufacturing method of the wiring substrate 20 according to the present embodiment involves a step of forming the etching barrier layer 26 after formation of the metal pad 12, wherein the etching barrier layer 26 is formed to cover the side surface of the metal pad 12. With this, the adhesion between the side surface of the metal pad 12 and the insulating layer 15 can be improved, and dispersion of metals into the insulating layer 15 can be suppressed. As a result, deterioration and peeling of the insulating layer 15 can be suppressed, and peeling of the insulating layer 15 from the upper surface of the metal pad 12 can be suppressed, as in Embodiment 1.

While the present disclosure is described with reference to embodiments, the present disclosure is not limited to these embodiments. It is obvious to the persons skilled in the art that various modifications, improvements, combinations or the like can be made.

While the above-described Embodiments 1 and 2 concern examples in which the planar shapes of the opening section 15a and the metal pad 12 are circular shapes and the planar shapes of the etching barrier layers 16 and 26 are annular shapes, the planar shapes are not limited to these shapes. For example, the planar shapes may be a polygonal shape, such as square, rectangle, or hexagon, or an elliptical shape. The planar shapes may be a polygonal shape with chamfered corners.

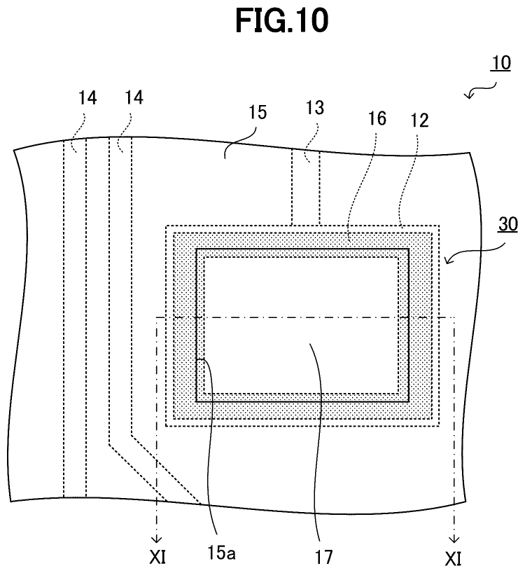

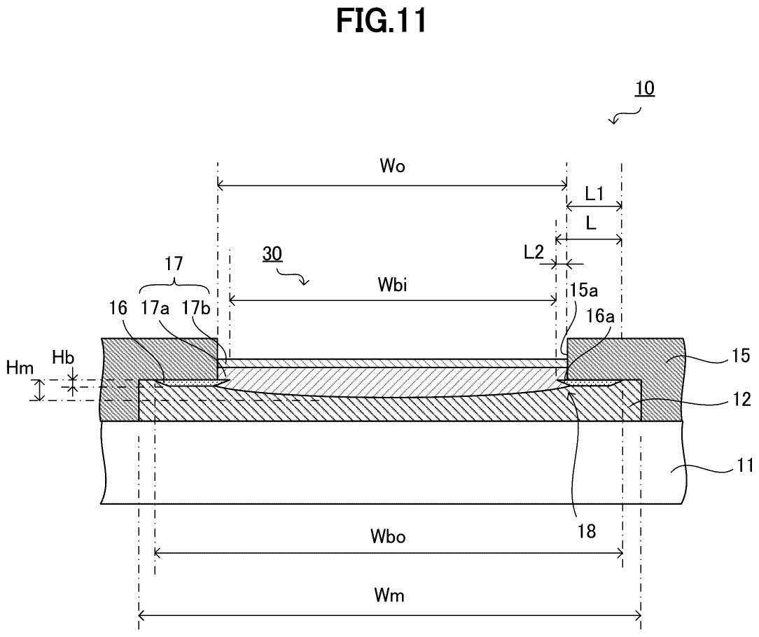

FIG. 10 illustrates a modified embodiment of the wiring substrate 10 according to Embodiment 1. Furthermore, FIG. 11 is a sectional view taken along the line XI-XI shown in FIG. 10. For example, as illustrated in FIGS. 10 and 11, the metal pad 12 and the opening section 15a may be formed to have rectangular planar shapes. The etching barrier layer 16 may be formed to have a rectangular frame shape in a plan view.

Furthermore, in the case where the planar shapes are rectangular, the inequality Wbi≤Wo<Wm is satisfied, where Wm denotes the width of the metal pad 12, Wo denotes the width of the opening section 15a of the insulating layer 15, Wbi denotes the width of the opening of the etching barrier layer 16, and Wbo denotes the width of the contour of the etching barrier layer 16. Similarly, the length L2 of the protrusion section 16a of the etching barrier layer 16 satisfies the inequality L2≥0. In a case where the planar shapes are rectangular, the widths may be defined in a longitudinal direction section as illustrated in FIG. 11, for example. Alternatively, the width may be defined in a transverse direction section or a diagonal section, instead of a longitudinal direction section. The same holds true for the wiring substrate 20 according to Embodiment 2.

Furthermore, while semiconductor package substrates are used as examples of the wiring substrates in the above-described embodiments, the wiring substrates are not limited to semiconductor package substrates. The wiring substrates may be printed circuit boards provided that a semiconductor device can be mounted on them. Furthermore, the wiring substrates may be single-sided boards, double-sided boards, multi-layer boards, or the like.

Furthermore, the above-described embodiments described exemplary cases where the metal pad 12 and the opening section 15a have the same planar shape. However, these planer shapes may be the same or different to each other. Furthermore, the planar shapes may be any shapes.

While a semi additive method is described as an example of a manufacturing method of the metal pad in the above-described embodiments, the manufacturing method is not limited to this method. For example, any manufacturing method, such as a full additive method may be used.

The present disclosure allows for various embodiments and modifications without departing from the broader spirit and scope of the present disclosure. Furthermore, the above-described embodiments are for explaining the present disclosure and does not limit the scope of the present disclosure. That is, the scope of the present disclosure is defined by the appended claims, and not by the embodiments. Then, various modifications within the scope of the spirit of the claims and the disclosures equivalent to the claims is considered to be within the scope of the present disclosure.

1. A wiring substrate having, on a surface, a mounting pad for mounting a semiconductor device, the wiring substrate comprising:
a metal pad provided on one of main surfaces of a base material;
an insulating layer being provided to cover a side surface of the metal pad and at least part of an upper surface of the metal pad, and being provided with an opening section that exposes a part of the upper surface of the metal pad; and
a metal layer provided on the metal pad exposed through the opening section, wherein
a pad area of the mounting pad is defined by the opening section formed in the insulating layer, and
the wiring substrate further comprises an etching barrier layer provided between the upper surface of the metal pad and the insulating layer, the etching barrier layer being provided to surround a lower end of the opening section and extending outward from the lower end of the opening section toward an outer periphery.

2. The wiring substrate according to claim 1, wherein at least an end of the etching barrier layer on the opening section side is in contact with the metal layer.

3. The wiring substrate according to claim 1, wherein the etching barrier layer is made of a metal different from a metal of which the metal pad is made.

4. The wiring substrate according to claim 1, wherein the etching barrier layer is made of an inorganic material.

5. The wiring substrate according to claim 1, wherein an end of the etching barrier layer on the opening section side protrudes toward a center of the opening section, relative to an inner peripheral surface of the opening section.

6. The wiring substrate according to claim 1, wherein the etching barrier layer extends to an outer peripheral side edge of the metal pad and covers the side surface of the metal pad.

7. The wiring substrate according to claim 1, wherein an end of the etching barrier layer on the opening section side is located at the lower end of the opening section.

8. A manufacturing method of a wiring substrate having, on a surface, a mounting pad for mounting a semiconductor device, the manufacturing method includes steps of:
forming an etching barrier layer on a metal pad provided on one of main surfaces of a base material;
forming an insulating layer covering a side surface of the metal pad and at least part of an upper surface of the metal pad, and being provided with an opening section that exposes a part of the upper surface of the metal pad; and
forming a metal layer on the metal pad exposed through the opening section, wherein
a pad area of the mounting pad is defined by the opening section formed in the insulating layer, and
the etching barrier layer is formed to surround a lower end of the opening section and extend outward from the lower end of the opening section toward an outer periphery.

9. The manufacturing method of the wiring substrate according to claim 8, wherein the metal layer is formed to be in contact with at least an end of the etching barrier layer on the opening section side.

10. The manufacturing method of the wiring substrate according to claim 8, wherein the etching barrier layer is made of a metal different from a metal of which the metal pad is made.

11. The manufacturing method of the wiring substrate according to claim 8, wherein the etching barrier layer is made of an inorganic material.

12. The manufacturing method of the wiring substrate according to claim 8, wherein an end of the etching barrier layer on the opening section side is formed to protrude toward a center of the opening section, relative to an inner peripheral surface of the opening section.

13. The manufacturing method of the wiring substrate according to claim 8, wherein the etching barrier layer is formed to extend to an outer peripheral side edge of the metal pad and cover the side surface of the metal pad.

14. The manufacturing method of the wiring substrate according to claim 8, wherein an end of the etching barrier layer on the opening section side is formed to locate at the lower end of the opening section.
